(19) United States
(12) Patent Application Publication
(10) Pub. No.: US 2009/0046281 A1
(43) Pub. Date: Feb. 19, 2009

(54) Method and System for Automated Inspection System Characterization and Monitoring

(76) Inventors: Joseph Straub, Round Rock, TX (US); Colleen Weins, Austin, TX (US); Anthony Nhiev, Pflugerville, TX (US); John Riddick, Taylor, TX (US); Daniel Aguilar, Austin, TX (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/839,964

(22) Filed: Aug. 16, 2007

(51) Int. Cl. G01N 21/88; G03F 1/00

(52) U.S. Cl. 356/237.5; 430/5

(57) ABSTRACT

A method and system characterizing and monitoring an automated inspection system are provided. A method for automatically characterizing an automatic inspection system for photomasks may include removing portions of an optical attenuator layer disposed on a substrate in order to expose portions of the substrate and create a plurality of test features. The may further include forming a plurality of programmed defects, on the optical attenuator layer, the plurality of programmed defects comprising at least one of an optical reflector and an optical absorber.

### TECHNICAL FIELD

This invention relates in general to photolithography and, more particularly, a method and system for monitoring and characterizing an automated inspection system.

### BACKGROUND

As device manufacturers continue to produce smaller and more complicated devices, photomasks used to fabricate these devices continue to require a wider range of capabilities. Photomasks, also known as reticles or masks, typically consist of substrates that have a patterned layer formed on the substrate. The patterned layer typically includes a pattern formed in an absorber material (e.g., chrome and/or other suitable materials) that represents an image that may be transferred onto a wafer in a lithography system.

Defects located on manufactured photomasks are a major source of yield loss in photomask manufacturing. For example, defects may cause errors in the transfer of an image onto a wafer in a photolithographic process. When a defect is discovered on a photomask, the defect must often be repaired or the photomask must be rejected.

Defects are often detected with automated inspection systems that compare geometries formed on a photomask with manufacturing data used to form the photomask. By comparing geometries formed on the photomask with manufacturing data used to form the photomask, areas and/or geometries on the photomask that may contain defects can be identified.

In addition, automated inspection systems may also detect defects not related to the geometries formed on a photomask during manufacturing. For example, in certain embodiments, automated inspection systems may be used to detect defects caused by contamination in a photomask. For example, exposure to electromagnetic radiation may, in certain instances, cause chemical changes in a photomask leading to defects. As another example, a photomask may become exposed to environmental contaminants (e.g., dust particles). Such contaminant defects may undesirably alter the optical properties of a photomask, thus leading to yield loss.

Because of the importance in detecting photomask defects, it is critical that the functionality of an automated inspection system and its sensitivity to defects be well-maintained. However, for any number of reasons (e.g., contamination of an automated inspection system, obsolescence and/or “wear and tear”), the sensitivity and/or functionality of an automated inspection system may degrade.

In order to monitor and characterize the functionality and/or sensitivity of an automated inspection system, it is common practice to use test photomasks comprising one or more known intentionally programmed defects. The test defects are typically patterned on a photomask in the same manner and with the same material as the mask features. During inspection, the area with the test defects is compared against a manufacturing design that does not contain the test defects or compared against an adjacent area on the photomask patterned without the test defects. By performing such comparison, one may monitor or characterize the automated inspection system's functionality and/or sensitivity. For example, the comparison may identify the number and/or sizes of test defects that are detected, and such identification of the number and/or sizes of test defects detected may provide an indication of the sensitivity of the automated inspection system. Common test photomasks produced in this manner (i.e., where the test defects are patterned on a photomask in the same manner as mask features) are often not sufficient to replicate defects caused by contamination.

To monitor and characterize an automated inspection system's functionality and sensitivity with respect to contamination-type defects, test photomasks with particles of a known size and distribution that mimic contamination-type defects may be used. In certain applications, polystyrene latex (PSL) spheres are deposited on a patterned photomask, for example, as described in U.S. Pat. No. 5,214,486. However, it has been found that PSL spheres may degrade when exposed to electromagnetic energy such as a DUV light source that may be used in an automated inspection system. Consequently, the changing of the size and physical characteristics of PSL spheres in a test photomask may be undesirable for use in methods and systems designed to monitor and characterize performance of automated inspection systems.

### SUMMARY OF THE DISCLOSURE

In accordance with teachings of the present disclosure, disadvantages and problems associated with monitoring and characterizing performance of an automated inspection system have been substantially reduced or eliminated. In a particular embodiment, a test photomask including programmed defects may be used to monitor and characterize the performance of an automated inspection system for photomasks.

In accordance with one embodiment of the present invention, a method for manufacturing a test photomask for use in the characterization of a photomask automated inspection system is provided. The method may include removing portions of an optical attenuator layer disposed on a substrate in order to expose portions of the substrate and create a plurality of test features. The may further include forming a plurality of programmed defects, on the optical attenuator layer, the plurality of programmed defects comprising at least one of an optical reflector and an optical absorber.

In accordance with another embodiment of the present invention, a test photomask for use in the characterization of a photomask automated inspection system may include a plurality of features and a plurality of programmed defects. The plurality of features may be formed in an optical attenuator layer disposed on a substrate, and the features may correspond to portions substrate substantially free of optical attenuator. The plurality of programmed defects may be formed on the optical attenuator layer, and the plurality of programmed defects may comprise at least one of an optical reflector and an optical absorber.

In accordance with yet another embodiment of the present disclosure, a method for characterizing an automated inspection system for photomasks is provided. The method may include providing a test photomask. The test photomask may include a plurality of features formed in an optical attenuator layer disposed on a substrate, and the features may correspond to portions of the substrate substantially free of optical attenuator. The test photomask may also include a plurality of programmed defects formed on the optical attenuator layer, and the plurality of programmed defects may comprise at least one of an optical reflector and an optical absorber. The method may further include inspecting the test photomask with an automated inspection system. In addition, the method may include determining which programmed defects are identified by the automated inspection system. Further, the method may include analyzing the detected programmed defects to characterize the automated inspection system.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates a cross-sectional view of a photomask assembly according to teachings of the present disclosure;

FIG. 2 illustrates a photolithography system that images a pattern created by a patterned layer and clear areas on a photomask onto the surface of a photolithographic component, according to teachings of the present disclosure;

FIG. 3 illustrates an example test photomask for monitoring and characterizing an automated inspection system, according to the teachings of the present disclosure;

FIG. 4A illustrates an example defect test cell formed on a photomask for monitoring and characterizing an automated inspection system, according to the teachings of the present disclosure;

FIG. 4B illustrates an example reference cell formed on a photomask for monitoring and characterizing an automated inspection system, according to the teachings of the present disclosure;

FIG. 5A illustrates another example defect test cell formed on a photomask for monitoring and characterizing an automated inspection system, according to the teachings of the present disclosure;

FIG. 5B illustrates another example reference cell formed on a photomask for monitoring and characterizing an automated inspection system, according to the teachings of the present disclosure;

FIG. 6 illustrates a flow diagram for an example method of characterizing an automated inspection system, according to the teachings of the present disclosure;

FIGS. 7A-7H illustrate various stages in the fabrication process of a test photomask, according to the teachings of the present disclosure; and

FIG. 8 illustrates a flow diagram for an example method for manufacturing a test photomask, according to the teachings of the present disclosure.

### DETAILED DESCRIPTION

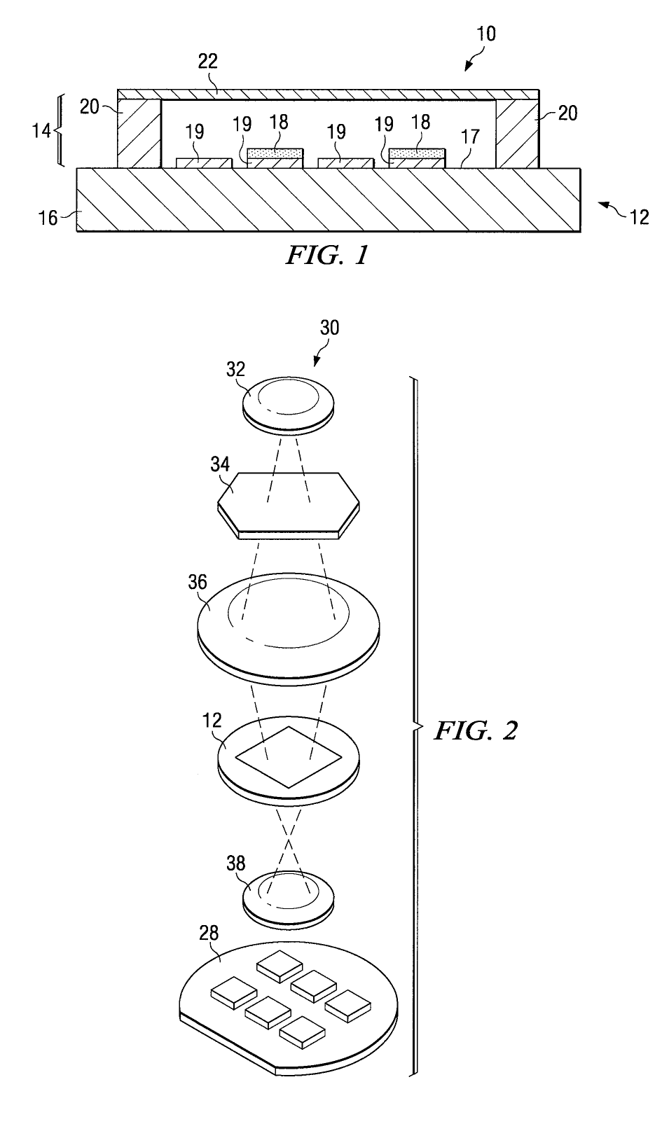

Preferred embodiments of the present disclosure and their advantages are best understood by reference to FIGS. 1 through 8, where like numbers are used to indicate like and corresponding parts.

FIG. 1 illustrates a cross-sectional view of an example photomask assembly 10. Photomask assembly 10 includes pellicle assembly 14 mounted on photomask 12. Substrate 16 and patterned layers 18 and 19 form photomask 12, otherwise known as a mask or reticle, that may have a variety of sizes and shapes, including but not limited to round, rectangular, or square. Photomask 12 may also be any variety of photomask types, including, but not limited to, a one-time master, a five-inch reticle, a six-inch reticle, a nine-inch reticle or any other appropriately sized reticle that may be used to project an image of a circuit pattern onto a semiconductor wafer. Photomask 12 may further be a binary mask, a phase shift mask (PSM) (e.g., an alternating aperture phase shift mask, also known as a Levenson type mask, and/or an embedded-attenuated phase-shift mask, also known as an EAPSM), an optical proximity correction (OPC) mask or any other type of mask suitable for use in a lithography system. In other embodiments, photomask 12 may be a step and flash imprint lithography (SFIL) template used to form an imprint of a pattern in a polymerizable fluid composition that solidifies to form a device on a wafer. The template may be a semi-transparent material, and the polymerizable fluid may be solidified by exposure to a radiation source in order to form the device on the wafer.

Photomask 12 includes patterned layers 18 and 19 formed on top surface 17 of substrate 16 that, when exposed to electromagnetic energy in a lithography system, projects a pattern onto a surface of a photolithographic component, e.g., a semiconductor wafer (not expressly shown). In some embodiments, substrate 16 may be a transparent material such as quartz, synthetic quartz, fused silica, magnesium fluoride (MgF₂), calcium fluoride (CaF₂), or any other suitable material that transmits at least seventy-five percent (75%) of incident light having a wavelength between approximately 10 nanometers (nm) and approximately 450 nm. In an alternative embodiment, substrate 16 may be a reflective material such as silicon or any other suitable material that reflects greater than approximately fifty percent (50%) of incident light having a wavelength between approximately 10 nm and approximately 450 nm.

In some embodiments, each of patterned layers 18 and 19 may be a metal material such as chrome, chromium nitride, a metallic oxy-carbo-nitride (e.g., MOₓC_{y}N_{z}, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and extreme ultraviolet range (EUV). In the same or alternative embodiments, each of patterned layers 18 and 19 may be a partially transmissive material, also known as an “attenuator material” such as molybdenum silicide (MoSi), which has a transmissivity of approximately one percent (1%) to approximately thirty percent (30%) in the UV, DUV, VUV and EUV ranges. In the embodiment depicted in FIG. 1, patterned layer 18 may comprise an absorber and/or reflective material while patterned layer 19 may comprise an attenuator material.

Frame 20 and pellicle film 22 may form pellicle assembly 14. Frame 20 is typically formed of anodized aluminum, although it could alternatively be formed of stainless steel, plastic or other suitable materials that do not degrade or outgas when exposed to electromagnetic energy within a lithography system. Pellicle film 22 may be a thin film membrane formed of a material such as nitrocellulose, cellulose acetate, an amorphous fluoropolymer, such as TEFLON® AF manufactured by E. I. du Pont de Nemours and Company or CYTOP® manufactured by Asahi Glass, or another suitable film that is transparent to wavelengths in the UV, DUV, EUV and/or VUV ranges. Pellicle film 22 may be prepared by a conventional technique such as spin casting, for example.

Pellicle film 22 may protect photomask 12 from contaminants, such as dust particles, by ensuring that the contaminants remain a defined distance away from photomask 12. This may be especially important in a lithography system. During a lithography process, photomask assembly 10 may be exposed to electromagnetic energy produced by a radiant energy source within the lithography system. The electromagnetic energy may include light of various wavelengths, such as wavelengths approximately between the I-line and G-line of a Mercury arc lamp, or DUV, VUV or EUV light. In operation, pellicle film 22 may be designed to allow a large percentage of the electromagnetic energy to pass through it. Contaminants collected on pellicle film 22 will likely be out of focus at the surface of the wafer being processed and, therefore, the exposed image on the wafer should be clear. Pellicle film 22 formed in accordance with the teachings of the present disclosure may be satisfactorily used with all types of electromagnetic energy and is not limited to lightwaves as described in this application.

Photomask 12 may be formed from a photomask blank using a standard lithography process. In a lithography process, a mask pattern file that includes data for patterned layer 18 may be generated from a mask layout file. In one embodiment, the mask layout file may include polygons that represent transistors and electrical connections for an integrated circuit. The polygons in the mask layout file may further represent different layers of the integrated circuit when it is fabricated on a semiconductor wafer. For example, a transistor may be formed on a semiconductor wafer with a diffusion layer and a polysilicon layer. The mask layout file, therefore, may include one or more polygons drawn on the diffusion layer and one or more polygons drawn on the polysilicon layer. In the same or alternative embodiments, the mask layout file may include polygons or shapes that represent features to be fabricated in and/or upon magnetic memory devices, micro-electrical mechanical systems (MEMS), biological MEMS (bio-MEMS), and/or optics devices.

In electrical and/or integrated circuit applications, the polygons for each layer may be converted into a mask pattern file that represents one layer of an integrated circuit. In such an application, each mask pattern file may be used to generate a photomask for the specific layer. In some embodiments, the mask pattern file may include more than one layer of an integrated circuit such that a photomask may be used to image features from more than one layer onto the surface of a semiconductor wafer, as set forth in greater detail in FIG. 2. In the same or alternative embodiments, the polygons for each layer may represent a feature to be fabricated in and/or upon magnetic memory devices, micro-electrical mechanical systems (MEMS), biological MEMS (bio-MEMS), and/or optics devices.

In certain embodiments, one or more polygons in a mask pattern file may not represent actual electrical, mechanical or optical components, but may be present only to assist in the lithographic process. For example, one or more polygons may comprise sub-resolution assist features (SRAFs), also known as “scattering bars,” “serifs” and/or simply “assist features,” that take advantage of the fact that edges of near-and sub-wavelength features located in dense areas of a photomask are typically resolved more sharply in a photolithographic system, as compared to isolated features. Accordingly, a SRAF is a feature that may be printed on a photomask near an existing feature to improve the imaged resolution of the existing feature as if the existing feature were in a densely packed area. The SRAFs, however, may be so narrow that they do not appear on a substrate imaged by the photomask—hence the name “sub-resolution.”

The desired pattern may be imaged into a resist layer of the photomask blank using a laser, electron beam or X-ray lithography system, for example. In one embodiment, a laser lithography system uses an argon-ion laser that emits light having a wavelength of approximately 364 nanometers (nm). In other embodiments, the laser lithography system may use lasers emitting light at wavelengths from approximately 150 nm to approximately 450 nm. In further embodiments, a 25 keV or 50 keV electron beam lithography system uses a lanthanum hexaboride or thermal field emission source. In the same or alternative embodiments, an electron beam lithography system uses a vector-shaped electronic beam lithography tool. In further embodiments, different electron beam lithography systems may be used. Photomask 12 may be fabricated by developing and etching exposed areas of the resist layer to create a pattern, etching the portions of patterned layer 18 and/or 19 not covered by resist, and removing the undeveloped resist to create patterned layer 18 and/or 19 over substrate 16.

FIG. 2 illustrates photolithography system 30 that images a pattern created by patterned layers 18 and 19 on photomask 12 onto the surface of photolithographic component 28. Photolithography system 30 may include light source 32, filter 34, condenser lens 36 and reduction lens 38. In one embodiment, light source 32 may be a mercury vapor lamp that emits wavelengths between approximately 350 nm and 450 nm. In another embodiment, light source 32 may be an argon-ion laser that emits a wavelength of approximately 364 nm. In other embodiments, light source 32 may emit wavelengths between approximately 150 nm and approximately 350 nm. Filter 34 may select the wavelength to be used in photolithography system 30 and condenser lens 36 and reduction lens 38 may use refractive optics to focus the radiant energy from light source 32 respectively onto photomask 12 and photolithographic component 28.

During a photolithography process, electromagnetic energy may illuminate photomask 12 and an image of the pattern on photomask 12 may be projected onto photolithographic component 28. The pattern on photomask 12 may be reduced by reduction lens 38 such that the image is only projected on a portion of photolithographic component 28. Photolithography system 30 may then realign photolithographic component 28 so that the pattern from photomask 12 may be imaged onto another portion of photolithographic component 28. The process may be repeated until all or most of the surface of photolithographic component 28 is covered by multiple instances of the pattern from photomask 12.

In accordance with the present disclosure, photolithographic component 28 may include, without limitation, photomasks, semiconductor wafers (e.g., silicon and gallium arsenide wafers), thin film transistor array substrates (e.g., for use in the manufacture of LCDs, flat panel displays and color filters), glass masters (e.g., for use in the manufacture of compact disks and DVDs), or any other suitable substrate which can be processed using photolithography.

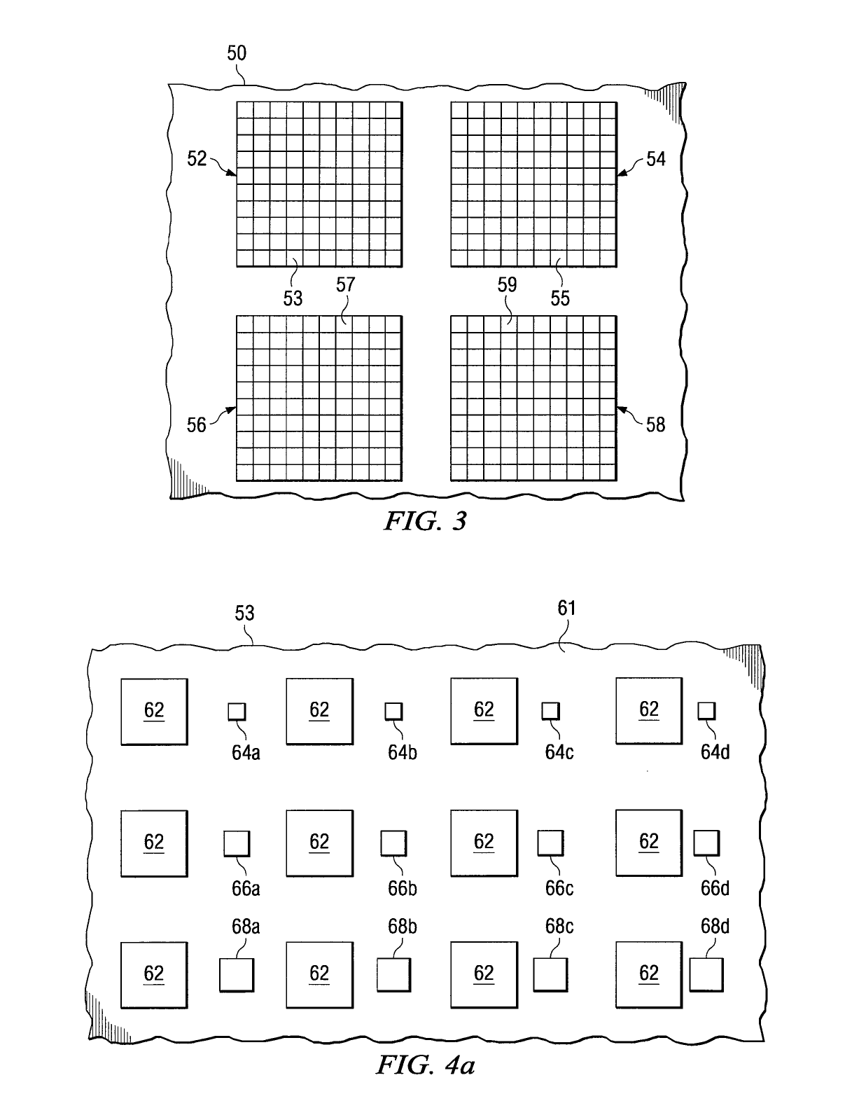

FIG. 3 illustrates a top view of an example test photomask 50 useful for monitoring and characterizing an automated inspection system. In certain embodiments, test photomask 50 may be an embedded-attenuated phase shift mask (EAPSM). Although the discussion of FIGS. 3 through 5B below may focus generally on embodiments in which test photomask 50 is an EAPSM, it is understood that test photomask 50 may be any suitable type and/or classification of photomask.

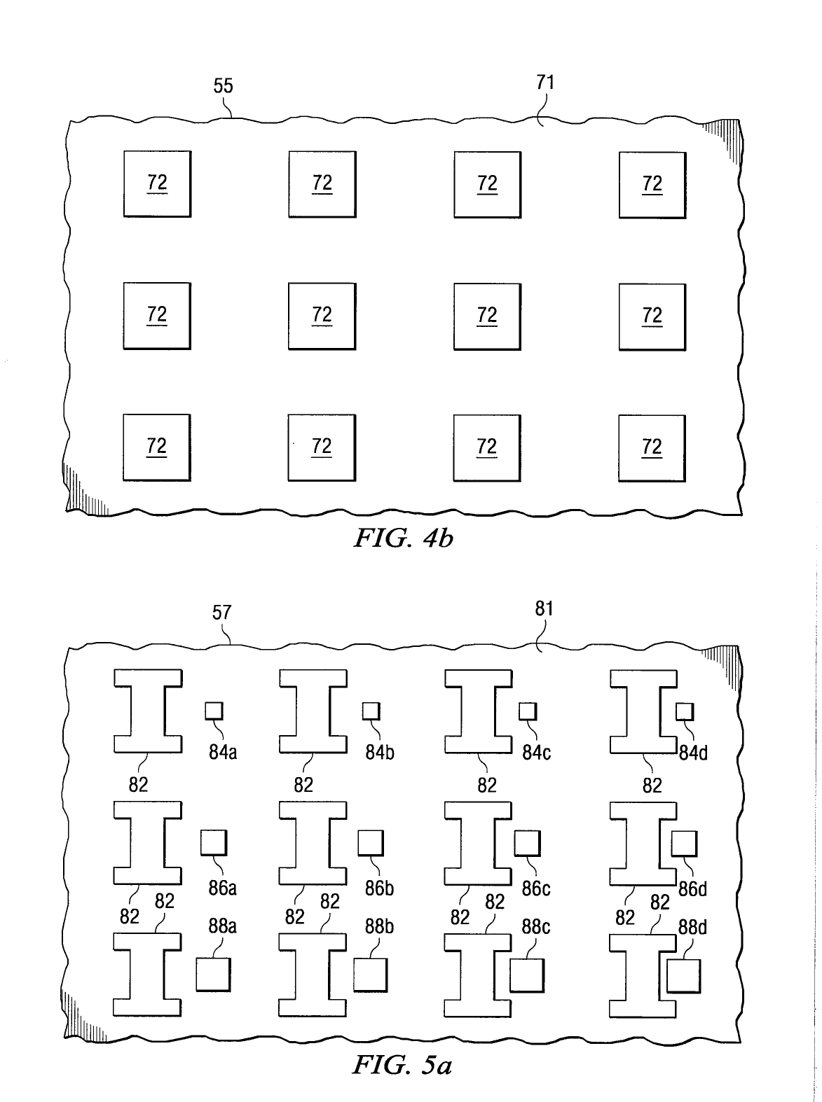

As depicted in FIG. 3, test photomask 50 may comprise attenuator layer test defect field 52, attenuator layer reference field 54, clear layer test defect field 56, and clear layer reference field 58. In general, attenuator layer test defect field 52 may include one or more cells (e.g., cell 53). Each cell of attenuator layer test defect field 52 may include a pattern of one or more features formed in an attenuator layer, along with one or more test defects to mimic contaminant-type defects, as described in greater detail with respect to FIG. 4A. Attenuator layer reference field 54 may include one more cells (e.g., cell 55), wherein each cell of attenuator layer reference field 54 may include a pattern of one or more features formed in an attenuator layer, but without any test defects mimicking contaminant-type defects, as described in greater detail with respect to FIG. 4B. In some embodiments, each cell of attenuator layer reference field 54 may correspond to a respective cell of attenuator layer test defect field 52. Accordingly, an automated inspection system may scan test photomask 50 for defects in each of fields 52 and 54, and by comparing (either manually or automatically) the defects detected in field 52 with the defects detected in field 54, the sensitivity of the automated inspection system to contaminant-type defects in an attenuator layer may be determined. Alternatively, in other embodiments, photomask 50 may not include attenuator layer reference field 54; instead, attenuator layer test defect field 52 may be inspected using an automatic inspection system that may detect contaminant-like without comparison to a reference field (e.g., a STARlight™ inspection tool manufactured by KLA-Tencor).

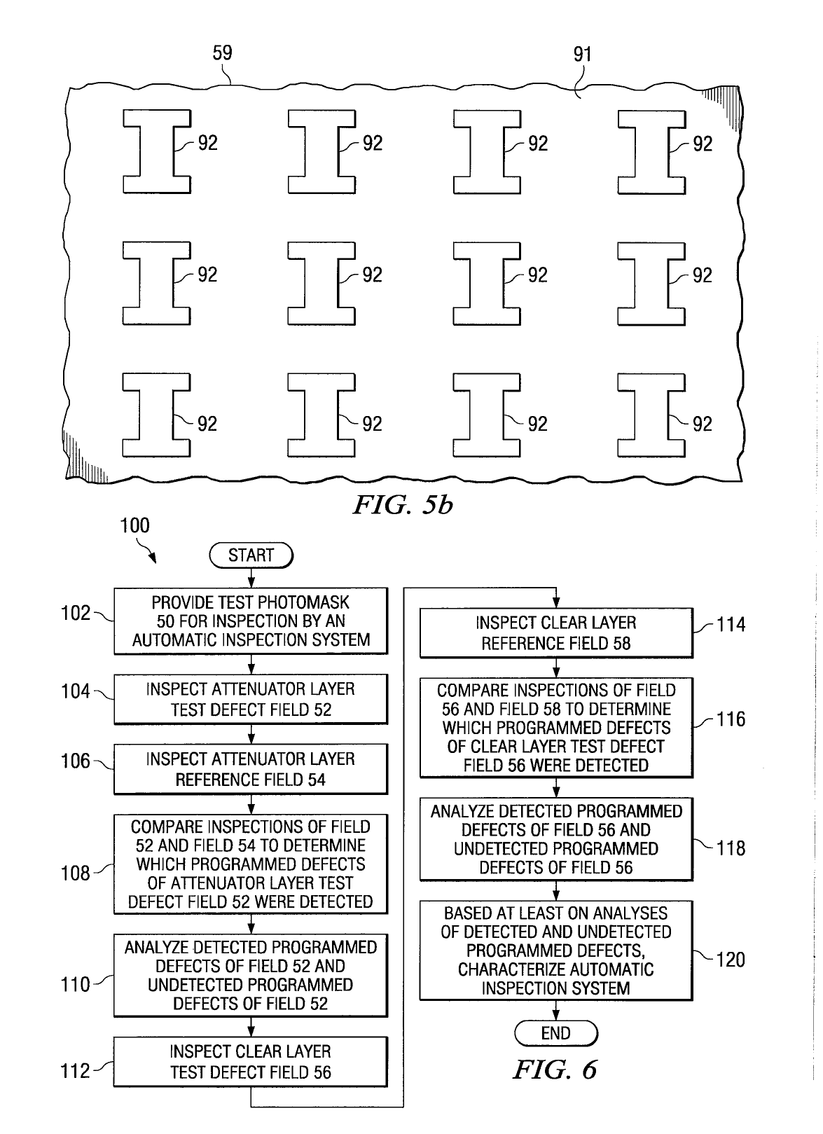

Similarly, clear layer test defect field 56 may include one or more cells (e.g., cell 57). Each cell of clear layer test defect field 56 may include a pattern of one or more features formed on an otherwise “clear” layer (e.g., a photomask substrate with no patterned layers formed thereon) along with one or more test defects to mimic contaminant-type defects, as described in greater detail with respect to FIG. 5A. Clear layer reference field 58 may include one more cells (e.g., cell 59), wherein each cell of clear layer reference field 58 may include a pattern of one or more features formed in an otherwise clear layer, but without any test defects mimicking contaminant-type defects, as described in greater detail with respect to FIG. 5B. In some embodiments, each cell of clear layer reference field 58 may correspond to a respective cell of clear layer test defect field 56. Accordingly, an automated inspection system may scan test photomask 50 for defects in each of fields 56 and 58, and by comparing (either manually or automatically) the defects detected in field 56 with the defects detected in field 58, the sensitivity of the automated inspection system to contaminant-type defects in an clear layer may be determined. Alternatively, in other embodiments, photomask 50 may not include clear layer reference field 58; instead, clear layer test defect field 56 may be inspected using an automatic inspection system that may detect contaminant-like without comparison to a reference field (e.g., a STARlight™ inspection tool manufactured by KLA-Tencor).

FIG. 4A illustrates an example attenuator layer defect test cell 53 formed on test photomask 50. Generally, attenuator defect test cell 53 may be useful for monitoring and characterizing an automated inspection system. As depicted in FIG. 4A, attenuator layer defect test cell 53 may be formed primarily of attenuator material 61. In certain embodiments, attenuator material 61 may comprise molybdenum silicide (MoSi). In addition, one or more features 62 may be formed within attenuator material 61. As depicted in FIG. 4A, features 62 may comprise “clear” areas of test photomask 50 (e.g., areas of photomask substrate without any patterned layer formed thereon). In the same or alternative embodiments, features 62 may comprise material patterned onto test photomask 50 and/or patterned onto attenuator material 61 (e.g., a reflective material and/or absorber material). Furthermore, attenuator layer defect test cell 53 may also comprise one more programmed defects 64, 66 and 68 which may mimic contaminant-type photomask defects. In the depicted embodiment, programmed defects 64, 66 and 68 may be made of a reflective material (e.g., silicon and/or another suitable material) and/or absorber material (e.g., chromium and/or another suitable material). In other embodiments, programmed defects 64, 66 and 68 may be formed of another suitable material.

In certain embodiments, programmed defects 64, 66 and 68 may vary in size. For example, as shown in FIG. 4A, programmed defects 64 are smaller than programmed defects 66, which are in turn smaller than programmed defects 68. In the same or alternative embodiments, the distances between programmed defects 64, 66 and 68 may be varied. For example, as depicted in FIG. 4A, programmed defects 64b, 66b and 68b may be closer to a feature 62 as compared with programmed defects 64a, 66a, and 68a, respectively. Likewise, programmed defects 64c, 66c and 68c may be closer to feature 62 as compared with programmed defects 64b, 66b, and 68b, respectively, and programmed defects 64d, 66d and 68d may be closer to feature 62 as compared with programmed defects 64c, 66c, and 68c, respectively.

FIG. 4B illustrates an example attenuator layer reference cell 55 formed on test photomask 50. Generally, attenuator layer reference cell 55 may be used, in conjunction with attenuator layer defect test cell 53, to monitor and characterize an automated inspection system, according to the teachings of the present disclosure. As shown in FIG. 4B, attenuator layer reference cell 55 may be identical and/or similar to attenuator layer defect test cell 53, with the exception that attenuator layer reference cell 55 may not include programmed defects. For example, attenuator layer reference cell 55 may include attenuator material 71 which is identical or substantially similar to attenuator material 61, and may further comprise features 72 which are identical or substantially similar to features 71. However, attenuator layer reference cell 55 may not include structures similar to programmed defects 64, 66, and 68.

Consequently, in order to characterize an automated inspection system's functionality with respect to detecting contaminant-type defects, the automated inspection system may inspect each of attenuator layer defect test cell 53 and attenuator layer reference cell 55. The results of such inspection may be analyzed (either manually or automatically) to determine if one or more structures are present in attenuator layer defect test cell 53 that do not have a corresponding structure in attenuator layer reference cell 55 (e.g., programmed defects 64, 66 and 68). The automated inspection system may fail to identify one or more of programmed defects 64, 66 and 68. For example, the automated inspection system may fail to detect programmed defects 64, 66, 68 below a certain size and/or may fail to detect programmed defects 64, 66 and 68 within a certain distance from a feature 62. By analyzing (either manually or automatically) programmed defects 64, 66 and 68 and that were detected and programmed defects 64, 66 and 68 that were undetected, the functionality of the automated inspection system with respect to defects occurring on an attenuator material may be monitored and characterized (e.g., the sensitivity of the automated inspection system to contaminant-type defects in attenuator material 61 may be determined).

Although attenuator layer defect test cell 53 and attenuator layer reference cell 55 are depicted as residing on the same test photomask 50, it is understood that cell 53 and cell 55 may be formed on different test photomasks. For example, cell 53 may be formed on a test photomask 50 comprising test defect fields 52 and 56, while cell 55 may be formed on a separate test photomask 50 comprising reference fields 54 and 58. In addition, although each of cell 53 and cell 55 are depicted as comprising twelve (12) features 62 and 72, it is understood that each of cell 53 and cell 55 may comprise any number of features 62. Also, although features 62 and 72 are depicted as being a particular size and shape, it is understood that features 62 and 72 may be of any suitable size and/or shape. Furthermore, although cell 53 is depicted as comprising twelve (12) features 64, 66 and 68 of particular sizes, it is understood that cell 53 may comprise any number of features 64, 66 and 68 of any size.

Alternatively, in other embodiments, photomask 50 may not include attenuator layer reference cell 55; instead, attenuator layer defect test cell 53 may be inspected using an automatic inspection system that may detect contaminant-like without comparison to a reference cell (e.g., a STARlight™ inspection tool manufactured by KLA-Tencor).

FIG. 5A illustrates an example clear layer defect test cell 57 formed on test photomask 50. Generally, clear layer defect test cell 57 may be useful for monitoring and characterizing an automated inspection system. As depicted in FIG. 5A, clear layer defect test cell 57 may be formed primarily of substantially “clear” area 81 of test photomask 50 (e.g., an area of photomask substrate substantially clear of any patterned material formed thereon). In addition, one or more features 82 may be formed within clear area 81. As depicted in FIG. 5A, features 82 may comprise attenuator material (e.g., MoSi). In the same or alternative embodiments, features 82 may comprise any other suitable material patterned onto test photomask 50 (e.g., a reflective material and/or absorber material). Furthermore, clear layer defect test cell 57 may also comprise one or more programmed defects 84, 86 and 88 which may mimic contaminant-type photomask defects. In the depicted embodiment, programmed defects may comprise an absorber material. In the same or alternative embodiments, programmed defects 84, 86 and 88 may be made of a reflective material (e.g., silicon and/or another suitable material) and/or absorber material (e.g., chromium and/or another suitable material). In other embodiments, programmed defects 84, 86 and 88 may be formed of another suitable material.

In certain embodiments, programmed defects 84, 86 and 88 may vary in size. For example, as shown in FIG. 5A, programmed defects 84 are smaller than programmed defects 86, which are in turn smaller than programmed defects 88. In the same or alternative embodiments, the distances between programmed defects 84, 86 and 88 may be varied. For example, as depicted in FIG. 5A, programmed defects 84b, 86b and 88b may be closer to feature 82 as compared with programmed defects 84a, 86a, and 88a, respectively. Likewise, programmed defects 84c, 86c and 88c may be closer to feature 82 as compared with programmed defects 84b, 86b, and 88b, respectively, and programmed defects 84d, 86d and 88d may be closer to feature 82 as compared with programmed defects 84c, 86c, and 88c, respectively.

FIG. 5B illustrates an example clear layer reference cell 59 formed on test photomask 50. Generally, clear layer reference cell 59 may be used, in conjunction with clear layer defect test cell 57, to monitor and characterize an automated inspection system. As shown in FIG. 5B, clear layer reference cell 59 may be identical and/or similar to clear layer defect test cell 57, with the exception that clear layer reference cell 59 may not include programmed defects. For example, clear layer reference cell 59 may comprise attenuator material 91 which is identical or substantially similar attenuator material 81, and may further comprise features 92 which are identical or substantially similar to features 91. However, clear layer reference cell 59 may not include structures similar to programmed defects 84, 86, and 88.

Consequently, in order to characterize an automated inspection system's functionality with respect to detecting contaminant-type defects, the automated inspection system may inspect each of clear layer defect test cell 57 and clear layer reference cell 59. The results of such inspection may be analyzed (either manually or automatically) to determine if one or more structures are present in clear layer defect test cell 57 that do not have a corresponding structure in clear layer reference cell 59 (e.g., the programmed defects 84, 86 and 88). In some embodiments, the automated inspection system may fail to identify one or more of programmed defects 84, 86 and 88. For example, the automated inspection system may fail to detect programmed defects 84, 86 and 88 below a certain size and/or may fail to detect programmed defects 84, 86 and 88 within a certain distance from a feature 82. By analyzing (either manually or automatically) programmed defects 84, 86 and 88 that were detected and programmed defects 84, 86 and 88 that were undetected, the functionality of the automated inspection system with respect to defects occurring on a “clear” area of photomask 50 may be monitored and characterized (e.g., the sensitivity of the automated inspection system to contaminant-type defects in attenuator material 81 may be determined).

Although clear layer defect test cell 57 and clear layer reference cell 59 are depicted as residing on the same test photomask 50, it is understood that cell 57 and cell 59 may be formed on different test photomasks. For example, cell 57 may be formed on test photomask 50 comprising test defect fields 52 and 56, while cell 59 may be formed on a separate test photomask 50 comprising reference fields 54 and 58. In addition, although each of cell 57 and cell 59 are depicted as comprising twelve (12) of features 82 and 92, it is understood that each of cell 57 and cell 59 may comprise any number of features 82. Also, although features 82 and 92 are depicted as being a particular size and shape (e.g., “I-shaped”), it is understood that features 82 and 92 may be of any suitable size and/or shape. Furthermore, although cell 57 is depicted as comprising twelve (12) features 84, 86 and 88 of particular sizes, it is understood that cell 57 may comprise any number of features 84, 86 and 88 of any size.

Alternatively, in other embodiments, photomask 50 may not include clear layer reference cell 59; instead, clear layer defect test cell 57 may be inspected using an automatic inspection system that may detect contaminant-like without comparison to a reference cell (e.g., a STARlight™ inspection tool manufactured by KLA-Tencor).

Although particular configurations of cells 53, 55, 57 and 59 are discussed above, it is understood that the various cells of field 52, 54, 56 and 58 may comprise any number of configurations. As an illustration, in certain embodiments, one or more of the various cells of field 52 may comprise features and/or programmed defects with shapes and/or sizes different than those of other cells within field 52. For example, in some embodiments, each column of cells in field 52 may comprise differently-shaped features 62. As an example of such embodiments, each cell in the first column of field 52 may comprise horizontally-rectangular features 62, while each cell in the second column of field 52 may comprise vertically-rectangular features 62, each cell in the third column may comprise square features 62, and each cell in the fourth column may comprise I-shaped features 62. In the same or alternative embodiments, the sizes of features 62 and programmed defects 64, 66, and 68 of field 52 may vary. For example, in some embodiments, each row of cells in field 52 may be a scaled-version of the row or rows adjacent to it. As an example of such embodiments, the first row of cells in field 52 may comprise features 62 and programmed defects 64, 66 and 68 of a certain size, while the second row of cells in field 52 may be identical to the first row, except that the second row may be scaled-down or a “shrink” of the cells in the row above. Likewise, the third row may be a scaled-down version of the second row, and so on.

FIG. 6 illustrates a flow diagram for an example method 100 for characterizing an automated inspection system. In one embodiment, method 100 includes inspecting one or more test defect fields and one or more reference fields, comparing the results of the inspections, and analyzing the comparison to characterize an automated inspection system.

According to one embodiment, method 100 preferably begins at step 102. Teachings of the present disclosure may be implemented in a variety of configurations of test photomask 50. As such, the preferred initialization point for method 100 and the order of the steps 102-120 comprising method 100 may depend on the implementation chosen.

At step 102, test photomask 50 may be placed in an automated inspection system. At step 104, the automated inspection system may inspect attenuator layer test defect field 52. At step 106, the automated inspection system may inspect attenuator layer reference field 54. At step 108, the automated inspection system, a person, and/or a computing device may compare the inspections of field 52 and field 54 to determine which programmed defects of field 52 were detected by the automated inspection system. At step 110, the automated inspection system, a person, and/or a computing device may analyze the detected programmed defects of field 52 and undetected programmed defects of field 52.

At step 112, the automated inspection system may inspect clear layer test defect field 56. At step 114, the automated inspection system may inspect clear layer reference field 58. At step 116, the automated inspection system, a person, and/or a computing device may compare the inspections of field 56 and field 58 to determine which programmed defects of field 56 were detected by the automated inspection system. At step 118, the automated inspection system, a person, and/or a computing device may analyze the detected programmed defects of field 56 and undetected programmed defects of field 56. At step 120, the automated inspection system, a person, and/or a computing device, may, based at least on the analyses of steps 110 and 118, characterize the automated inspection system. For example, at step 120, the sensitivity of the automated inspection system to the detection of contaminant-type defects may be determined.

Although FIG. 6 discloses a particular number of steps to be taken with respect to method 100, it is understood that method 100 may be executed with greater or lesser steps than those depicted in FIG. 6. In addition, although FIG. 6 discloses a particular order of steps to be taken with respect to method 100, it is understood that steps 102-120 of method 100 may be executed in any order or manner consistent with the present disclosure. For example, in certain embodiments, steps 112-118 of method 100 may be executed prior to step 104.

Method 100 may be implemented using test photomask 50 or any other system, device or apparatus operable to implement method 100. In certain embodiments, method 100 may be implemented in part by software embodied in tangible computer readable media.

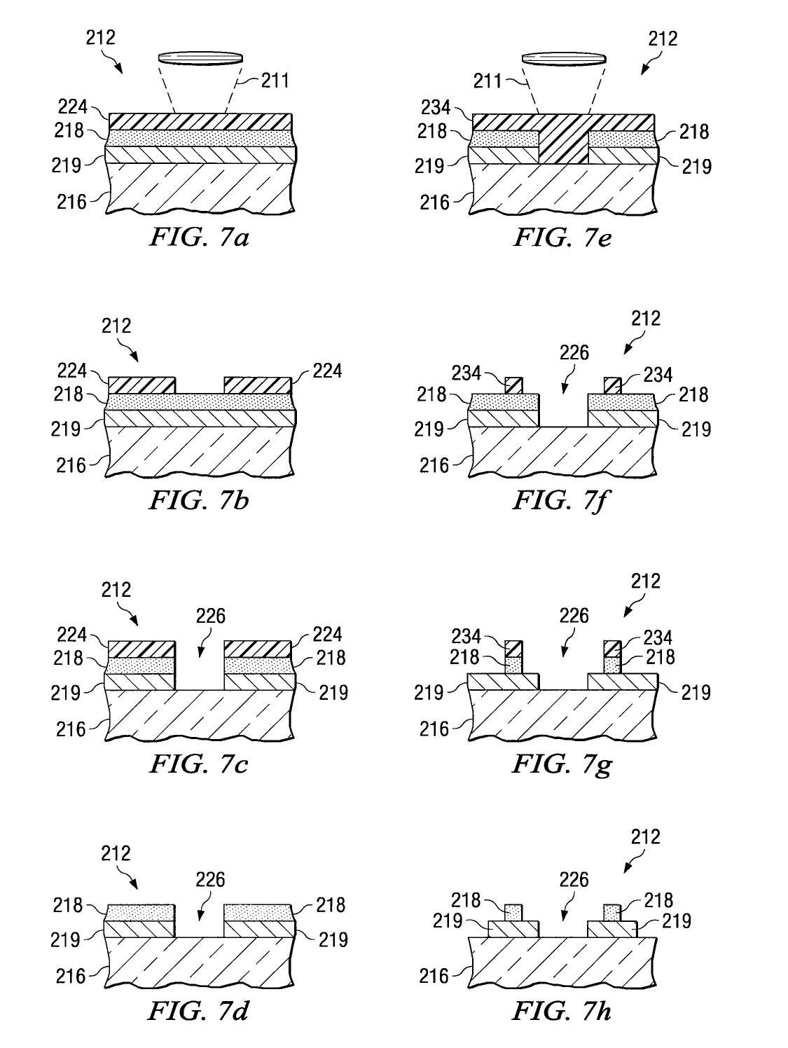

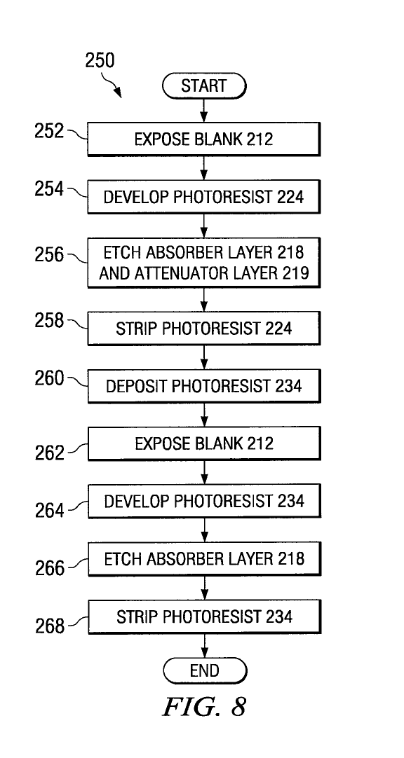

FIGS. 7A-7H depict a cross section of a portion of a test photomask. Specifically, FIGS. 7A-7H illustrate various stages in the fabrication process of a test photomask, e.g., test photomask 50, and more particularly, portions of test photomask 50 comprising attenuator layer test defect field 52 and attenuator layer reference field 54. The flowchart of FIG. 8 describes steps in the example method 250 for fabricating a test photomask.

According to one embodiment, method 250 preferably begins at step 252. Teachings of the present disclosure may be implemented with a variety of configurations of test photomask 50. As such, the preferred initialization point for method 250 and the order of the steps 252-268 comprising method 250 may depend on the implementation chosen.

Referring now to step 252 of method 250, a pattern may be exposed onto photomask blank 212. As depicted in FIG. 7A, photomask blank 212 may include transparent substrate 216, a layer of optical attenuator 219 that coats a surface of transparent substrate 216, a layer of optical absorber 218 that coats optical attenuator 219, and a layer of photoresist 224 that coats optical absorber 218. The test photomask manufacturer may expose the pattern in photoresist 224 using an electron beam or laser beam 211, for example.

At step 254, photoresist 224 may be developed which causes portions of photoresist 224 to be removed according to the pattern exposed in step 252, as shown in FIG. 7B. In the example embodiment of FIGS. 7A-7H a positive resist process is used, in which a developer dissolves the areas of photoresist 224 (or photoresist 234, discussed below) that have been exposed, to uncover regions of optical absorber 218 and/or optical attenuator 219 formed on transparent substrate 216. However, negative photoresist may be used in alternative embodiments. At step 256, optical absorber 218 and optical attenuator 219 may be etched away in the areas that have been cleared of photoresist 224 to expose areas of transparent substrate 216 to produce “clear” area 226, as shown in FIG. 7C.

At step 258, photoresist 224 may be stripped as depicted in FIG. 7D. At step 260, a photoresist 234 may be deposited on the structures remaining on photomask blank 212, as shown in FIG. 7E. In some embodiments, photoresist 234 may be identical or similar to photoresist 234. At step 262, a pattern may be exposed onto photoresist 234, as also shown in FIG. 7E. In some embodiments, the exposure of step 262 may use techniques similar and/or identical to those used in step 252.

At step 264, photoresist 234 may be developed which causes portions of photoresist 234 to be removed according to the pattern exposed in step 262, as shown in FIG. 7F. At step 266, optical absorber 218 may be etched away in the areas that have been cleared of photoresist 234 to expose areas of optical attenuator 219, as shown in FIG. 7G. At step 268, photoresist 234 may be stripped as depicted in FIG. 7H. After completion of step 268, method 250 may end.

Although FIG. 8 discloses a particular number of steps to be taken with respect to method 250, it is understood that method 250 may be executed with greater or lesser steps than those depicted in FIG. 8. For example, in certain embodiments, additional layers may be formed on photomask blank 212 (e.g., anti-reflecting coatings, protective coatings, etc.) and/or other components may be attached to or mounted on photomask blank 212 (e.g., a pellicle assembly). In addition, although FIG. 8 discloses a particular order of steps to be taken with respect to method 250, it is understood that steps 252-268 of method 250 may be executed in any order or manner consistent with the present disclosure.

Method 250 may be implemented using any suitable system, device or apparatus operable to implement method 250. In certain embodiments, method 250 may be implemented in part by software embodied in tangible computer readable media.

Method 250 set forth in FIG. 8 may allow a test photomask to be manufactured similar to that depicted in FIGS. 3-5B. For example, method 250 may be used to manufacture a test photomask including an attenuator layer test defect field 52 as depicted in FIGS. 3 and 4A. To illustrate, remaining optical attenuator 219 may correspond to attenuator layer 61 of cell 53, clear area 226 may correspond to features 62 of cell 53, and remaining optical absorber 218 may correspond to programmed defects 64, 66, and 68. Using methods similar to those disclosed with respect to FIGS. 7 and 8, test photomasks 50 with attenuator layer reference fields 54, clear layer test defect fields 56, and clear layer reference fields 58 may also be produced.

In accordance with teachings of the present disclosure, disadvantages and problems associated with monitoring and characterizing an automated inspection system have been substantially reduced or eliminated.

Although the present disclosure and its advantages have been described in detail, it should be understood that various changes, substitutions and alterations can be made herein without departing from the spirit and scope of the disclosure as defined by the following claims.

What is claimed is:

1. A method for manufacturing a test photomask for use in the characterization of a photomask automated inspection system, comprising:
removing portions of an optical attenuator layer disposed on a substrate in order to expose portions of the substrate and create a plurality of test features; and
forming a plurality of programmed defects, on the optical attenuator layer, the plurality of programmed defects comprising at least one of an optical reflector and an optical absorber.

2. The method of claim 1, wherein at least one of the plurality of programmed defects is of a different size than at least one other of the plurality of programmed defects.

3. The method of claim 1, wherein:
each of the plurality of programmed defects is located a predetermined distance from a corresponding test feature; and
the predetermined distance associated with at least one of the programmed defects is substantially different from the predetermined distance associated with at least one other of the programmed defects.

4. The method of claim 1, wherein:
each of the plurality of test features comprises a predetermined shape; and
the predetermined shape of at least one of the test features is different than the predetermined shape of at least one other of the test features.

5. The method of claim 1, further comprising removing additional portions of the optical attenuator layer in order to expose additional portions of the substrate to create a plurality of reference features, each reference feature substantially similar to a corresponding test feature.

6. The method of claim 1, further comprising:
forming second plurality of test features by exposing a second portion of the optical attenuator layer, each of the second plurality of test features comprising optical attenuator; and
forming, on at least a portion of the exposed substrate a plurality of programmed defects, each of the plurality of programmed defects comprising optical attenuator.

7. The method of claim 1, wherein at least one of the programmed defects represents a contaminant-type photomask defect.

8. The method of claim 7, wherein the test features and the programmed defects are operable to be inspected to characterize the sensitivity of an automated inspection system to contaminant-type photomask defects.

9. A test photomask for use in the characterization of a photomask automated inspection system, comprising:
a plurality of features formed in an optical attenuator layer disposed on a substrate, the features corresponding to portions substrate substantially free of optical attenuator; and
a plurality of programmed defects formed on the optical attenuator layer, the plurality of programmed defects comprising at least one of an optical reflector and an optical absorber.

10. The test photomask of claim 9, wherein at least one of the plurality of programmed defects is of a different size than at least one other of the plurality of programmed defects.

11. The test photomask of claim 9, wherein:
each of the plurality of programmed defects is located a predetermined distance from a corresponding test feature; and
the predetermined distance associated with at least one of the programmed defects is substantially different from the predetermined distance associated with at least one other of the programmed defects.

12. The test photomask of claim 9, wherein:
each of the plurality of test features comprises a predetermined shape; and
the predetermined shape of at least one of the test features is different than the predetermined shape of at least one other of the test features.

13. The test photomask of claim 9, further comprising a second plurality of reference features, each reference feature substantially similar to a corresponding test feature.

14. The test photomask of claim 9, further comprising:
on an exposed portion of the substrate a second plurality of test features, each of the second plurality of test features comprising optical attenuator; and
on the exposed portion of the substrate, a plurality of programmed defects, each of the plurality of programmed defects comprising optical attenuator.

15. The test photomask of claim 9, wherein at least one of the programmed defects represents a contaminant-type photomask defect.

16. The test photomask of claim 15, wherein the test features and the programmed defects may be inspected to characterize the sensitivity of an automated inspection system to contaminant-type photomask defects.

17. A method for characterizing an automated inspection system for photomasks, comprising:
providing a test photomask including:
a plurality of features formed in an optical attenuator layer disposed on a substrate, the features corresponding to portions of the substrate substantially free of optical attenuator; and
a plurality of programmed defects formed on the optical attenuator layer, the plurality of programmed defects comprising at least one of an optical reflector and an optical absorber;
inspecting the test photomask with an automated inspection system;
determining which programmed defects are identified by the automated inspection system; and
analyzing the detected programmed defects to characterize the automated inspection system.

18. The method of claim 17, wherein at least one of the plurality of programmed defects is of a different size than at least one other of the plurality of programmed defects.

19. The method of claim 17, wherein:
each of the plurality of programmed defects is of a predetermined distance from a corresponding test feature; and
the predetermined distance associated with at least one of the programmed defects is substantially different from the predetermined distance associated with at least one other of the programmed defects.

20. The method of claim 17, wherein:
each of the plurality of test features comprises a predetermined shape; and
the predetermined shape of at least one of the test features is different than the predetermined shape of at least one other of the test features.

21. The method of claim 17, further comprising removing additional portions of the optical attenuator layer in order to expose additional portions of the substrate to create a plurality of reference features, each reference feature substantially similar to a corresponding test feature.

22. The method of claim 17, the test photomask further comprising:
on an exposed portion of the substrate a second plurality of test features, each of the second plurality of test features comprising optical attenuator; and
on the exposed portion of the substrate, a plurality of programmed defects, each of the plurality of programmed defects comprising optical attenuator.

23. The method of claim 17, wherein at least one of the programmed defects represents a contaminant-type photomask defect.

24. The method of claim 23, further comprising characterizing the sensitivity of an automated inspection system to contaminant-type photomask defects.
